(19) United States
(12) Patent Application Publication
(10) Pub. No.: US 2022/0262863 A1
(43) Pub. Date: Aug. 18, 2022

(54) IMAGE SENSOR PIXEL

(71) Applicant: ISORG, Limoges CEDEX 3 (FR)

(72) Inventors: Camille DUPOIRON, GRENOBLE (FR); Benjamin BOUTHINON, GRENOBLE (FR)

(21) Appl. No.: 17/627,551

(22) PCT Filed: Jul. 16, 2020
(86) PCT No.: PCT/EP2020/070072

§ 371 Date: Jan. 14, 2022

(30) Foreign Application Priority Data
Jul. 19, 2019 (FR) FR1908251

(51) Int. Cl. H01L 27/30

(52) U.S. Cl. CPC H01L 27/307

(57) ABSTRACT

A pixel includes a CMOS support and at least two organic photodetectors. A same lens is vertically in line with the organic photodetectors.

The present patent application claims the priority benefit of French patent application FR19/08251, which is herein incorporated by reference.

### FIELD

The present disclosure relates to an image sensor or electronic imager.

### BACKGROUND

Image sensors are currently used in many fields, in particular in electronic devices. Image sensors are particularly present in man-machine interface applications or in image capture applications. The fields of use of such image sensors particularly are, for example, smart phones, motors vehicles, drones, robotics, and virtual or augmented reality systems.

In certain applications, a same electronic device may have a plurality of image sensors of different types. Such a device may thus comprise, for example, a first color image sensor, a second infrared image sensor, a third image sensor enabling to estimate a distance, relative to the device, of different points of a scene or of a subject, etc.

Such a multiplicity of image sensors embarked in a same device is, by nature, little compatible with current constraints of miniaturization of such devices.

### SUMMARY

There is a need to improve existing image sensors.

An embodiment overcomes all or part of the disadvantages of known image sensors.

An embodiment provides a pixel comprising:
a CMOS support; and
at least two organic photodetectors,
where a same lens is vertically in line with said organic photodetectors.

An embodiment provides an image sensor comprising a plurality of pixels such as described.

An embodiment provides a method of manufacturing such a pixel or such an image sensor, comprising steps of:
providing a CMOS support;
forming at least two organic photodetectors per pixel;
forming a same lens vertically in line with the organic photodetectors of the or of each pixel.

According to an embodiment, said organic photodetectors are coplanar.

According to an embodiment, said organic photodetectors are separated from one another by a dielectric.

According to an embodiment, each organic photodetector comprises a first electrode, separate from first electrodes of the other organic photodetectors, formed at the surface of the CMOS support.

According to an embodiment, each first electrode is coupled, preferably connected, to a readout circuit, each readout circuit preferably comprising three transistors formed in the CMOS support.

According to an embodiment, said organic photodetectors are capable of estimating a distance by time of flight.

According to an embodiment, the pixel or the sensor such as described is capable of operating:
in a portion of the infrared spectrum;
in structured light;
in high dynamic range imaging, HDR; and/or
with a background suppression.

According to an embodiment, each pixel further comprises, under the lens, a color filter giving way to electromagnetic waves in a frequency range of the visible spectrum and in the infrared spectrum.

According to an embodiment, the sensor such as described is capable of capturing a color image.

According to an embodiment, each pixel exactly comprises:
a first organic photodetector; and
a second organic photodetector.

According to an embodiment, for each pixel, the first organic photodetector and the second organic photodetector have a rectangular shape and are jointly inscribed within a square.

According to an embodiment, for each pixel:
the first organic photodetector is connected to a second electrode; and
the second organic photodetector is connected to a third electrode.

An embodiment provides a sensor wherein:
the second electrode is common to all the first organic photodetectors of the pixels of the sensor; and
the third electrode is common to all the second organic photodetectors of the pixels of the sensor.

### BRIEF DESCRIPTION OF THE DRAWINGS

The foregoing and other features and advantages of the present invention will be discussed in detail in the following non-limiting description of specific embodiments and implementation modes in connection with the accompanying drawings, in which:

FIG. 1 is a partial simplified exploded perspective view of an embodiment of an image sensor;

FIG. 2 is a partial simplified top view of the image sensor of FIG. 1;

FIG. 3 is an electric diagram of an embodiment of readout circuits of two pixels of the image sensor of FIGS. 1 and 2;

FIG. 4 is a timing diagram of signals of an example of operation of the image sensor having the readout circuits of FIG. 3;

FIG. 5 is a partial simplified cross-section view of a step of an implementation mode of a method of forming the image sensor of FIGS. 1 and 2;

FIG. 6 is a partial simplified cross-section view of another step of the implementation mode of the method of forming the image sensor of FIGS. 1 and 2;

FIG. 7 is a partial simplified cross-section view of still another step of the implementation mode of the method of forming the image sensor of FIGS. 1 and 2;

FIG. 8 is a partial simplified cross-section view of still another step of the implementation mode of the method of forming the image sensor of FIGS. 1 and 2;

FIG. 9 is a partial simplified cross-section view of still another step of the implementation mode of the method of forming the image sensor of FIGS. 1 and 2;

FIG. 10 is a partial simplified cross-section view of still another step of the implementation mode of the method of forming the image sensor of FIGS. 1 and 2;

FIG. 11 is a partial simplified cross-section view of a variant of the implementation mode of the method of forming the image sensor of FIGS. 1 and 2;

FIG. 12 is a partial simplified cross-section view of still another step of the implementation mode of the method of forming the image sensor of FIGS. 1 and 2;

FIG. 13 is a partial simplified cross-section view of still another step of the implementation mode of the method of forming the image sensor of FIGS. 1 and 2;

FIG. 14 is a partial simplified cross-section view along plane AA of the image sensor of FIGS. 1 and 2;

FIG. 15 is a partial simplified cross-section view along plane BB of the image sensor of FIGS. 1 and 2; and

FIG. 16 is a partial simplified cross-section view of another embodiment of an image sensor.

### DESCRIPTION OF THE EMBODIMENTS

Like features have been designated by like references in the various figures. In particular, the structural and/or functional elements common to the different embodiments and implementation modes may be designated with the same reference numerals and may have identical structural, dimensional, and material properties.

For clarity, only those steps and elements which are useful to the understanding of the described embodiments and implementation modes have been shown and will be detailed. In particular, what use is made of the image sensors described hereafter has not been detailed.

Unless specified otherwise, when reference is made to two elements connected together, this signifies a direct connection without any intermediate elements other than conductors, and when reference is made to two elements coupled together, this signifies that these two elements can be connected or they can be coupled via one or more other elements.

Further, a signal which alternates between a first constant state, for example, a low state, noted “0”, and a second constant state, for example, a high state, noted “1”, is called a “binary signal”. The high and low states of different binary signals of a same electronic circuit may be different. In particular, the binary signals may correspond to voltages or to currents which may not be perfectly constant in the high or low state.

In the following description, it is considered, unless specified otherwise, that the terms “insulating” and “conductive” respectively signify “electrically insulating” and “electrically conductive”.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., unless specified otherwise, it is referred to the orientation of the drawings or to an image sensor in a normal position of use.

Unless specified otherwise, the expressions “around”, “approximately”, “substantially” and “in the order of” signify within 10%, and preferably within 5%.

The transmittance of a layer to a radiation corresponds to the ratio of the intensity of the radiation coming out of the layer to the intensity of the radiation entering the layer, the rays of the incoming radiation being perpendicular to the layer. In the following description, a layer or a film is called opaque to a radiation when the transmittance of the radiation through the layer or the film is smaller than 10%. In the following description, a layer or a film is called transparent to a radiation when the transmittance of the radiation through the layer or the film is greater than 10%.

In the following description, “visible light” designates an electromagnetic radiation having a wavelength in the range from 400 nm to 700 nm and “infrared radiation” designates an electromagnetic radiation having a wavelength in the range from 700 nm to 1 mm. In infrared radiation, one can particularly distinguish near infrared radiation having a wavelength in the range from 700 nm to 1.7 μm.

A pixel of an image corresponds to the unit element of the image captured by an image sensor. When the optoelectronic device is a color image sensor, it generally comprises, for each pixel of the color image to be acquired, at least three components. The three components each acquire a light radiation substantially in a single color, that is, in a wavelength range below 130 nm (for example, red, green, and blue). Each component may particularly comprise at least one photodetector.

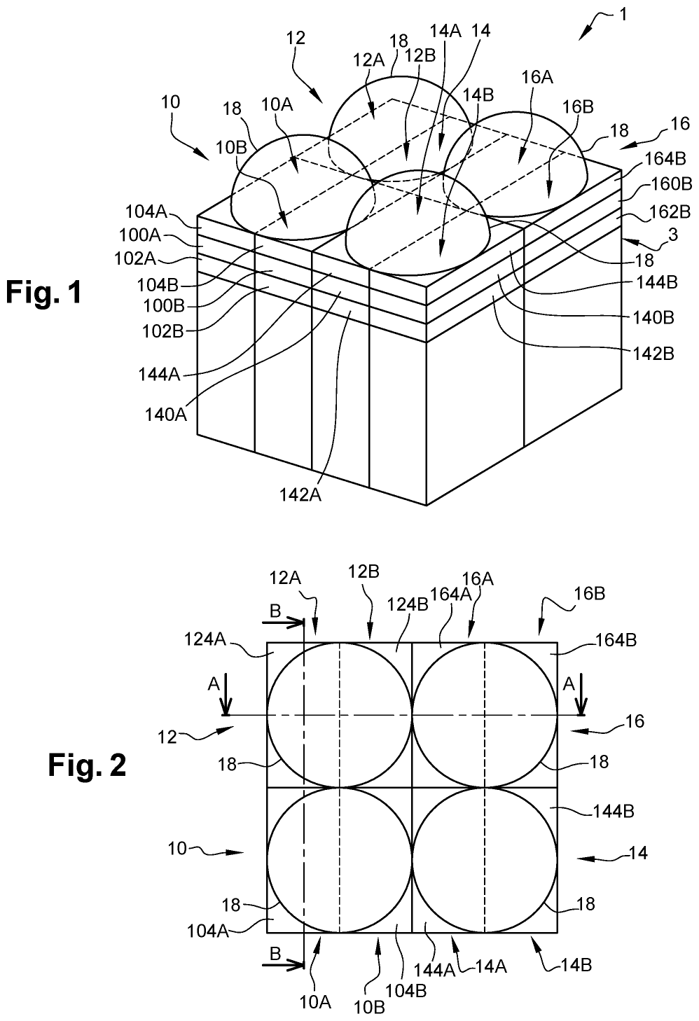

FIG. 1 is a partial simplified exploded perspective view of an embodiment of an image sensor 1.

Image sensor 1 comprises an array of coplanar pixels. For simplification, only four pixels 10, 12, 14, and 16 of image sensor 1 have been shown in FIG. 1, it being understood that, in practice, image sensor 1 may comprise more pixels. Image sensor 1 for example comprises several millions, or even several tens of millions of pixels.

According to this embodiment, pixels 10, 12, 14, and 16 are located at the surface of a CMOS support 3, for example, a piece of a silicon wafer on top and inside of which integrated circuits (not shown) have been formed in CMOS (Complementary Metal Oxide Semiconductor) technology. These integrated circuits form, in this example, an array of readout circuits associated with pixels 10, 12, 14, and 16 of image sensor 1. Readout circuit means an assembly of readout, addressing, and control transistors associated with each pixel.

In image sensor 1, each pixel comprises a first photodetector, designated with suffix “A”, and a second photodetector, designated with suffix “B”. More particularly, in the example of FIG. 1:
pixel 10 comprises a first photodetector 10A and a second photodetector 10B;
pixel 12 comprises a first photodetector 12A and a second photodetector 12B;
pixel 14 comprises a first photodetector 14A and a second photodetector 14B; and
pixel 16 comprises a first photodetector 16A and a second photodetector 16B.

Photodetectors 10A, 10B, 12A, 12B, 14A, 14B, 16A, and 16B may correspond to organic photodiodes (OPD) or to organic photoresistors. In the rest of the disclosure, it is considered that the photodetectors of the pixels of image sensor 1 correspond to organic photodiodes.

In the simplified representation of FIG. 1, each photodetector comprises an active layer located or “sandwiched” between two electrodes. More particularly, in the example of FIG. 1 where only lateral surfaces of organic photodetectors 10A, 10B, 14A, 14B, and 16B are visible:
the first photodetector 10A is formed of an active layer 100A between a first electrode 102A and a second electrode 104A;
the second photodetector 10B is formed of an active layer 100B between a first electrode 102B and a second electrode 104B;
the first photodetector 14A is formed of an active layer 140A between a first electrode 142A and a second electrode 144A;
the second photodetector 14B is formed of an active layer 140B between a first electrode 142A and a second electrode 144B; and
the second photodetector 16B is formed of an active layer 160B between a first electrode 162A and a second electrode 164B.

Similarly, in image sensor 1:
the first photodetector 12A is formed of an active layer 120A (not shown in FIG. 1) between a first electrode 122A (not shown in FIG. 1) and a second electrode 124A (not shown in FIG. 1);
the second photodetector 12B is formed of an active layer 120B (not shown in FIG. 1) between a first electrode 122B (not shown in FIG. 1) and a second electrode 124B (not shown in FIG. 1); and
the first photodetector 16A is formed of an active layer 160A (not shown in FIG. 1) between a first electrode 162A (not shown in FIG. 1) and a second electrode 164A (not shown in FIG. 1).

In the rest of the disclosure, the first electrodes will also be designated with the expression “lower electrodes” while the second electrodes will also be designated with the expression “upper electrodes”.

According to an embodiment, the upper electrode of each organic photodetector forms an anode electrode while the lower electrode of each organic photodetector forms a cathode electrode.

The lower electrode of each photodetector of each pixel of image sensor 1 is individually coupled, preferably connected, to a readout circuit (not shown) of CMOS support 3. Each photodetector of image sensor 1 is accordingly individually addressed via its lower electrode. Thus, in image sensor 1, each photodetector has a lower electrode separate from the lower electrodes of all the other photodetectors. In other words, each photodetector of a pixel has a lower electrode separate:
from the other photodetector of the same pixel; and
from the other photodetectors of the other pixels.

Still in image sensor 1, the upper electrodes of all the first photodetectors are interconnected. Similarly, the upper electrodes of all the second photodetectors are interconnected. Thus, in the simplified representation of FIG. 1:
the upper electrodes 104A, 124A, 144A, and 164A, respectively belonging to the first photodetectors 10A, 12A, 14A, and 16A are interconnected or form a first common upper electrode; and
the upper electrodes 104B, 124B, 144B, and 164B, respectively belonging to the first photodetectors 10B, 12B, 14B, and 16B are interconnected or form a second common upper electrode, separate from the first common upper electrode.

In image sensor 1, each pixel comprises a lens 18, also called microlens 18 due to its dimensions. Thus, in the simplified representation of FIG. 1, pixels 10, 12, 14, and 16 each comprise a lens 18. Each lens 18 thus covers all or part of the first and second photodetectors of each pixel of image sensor 1. More particularly, lens 18 physically covers the upper electrodes of the first and second photodetectors of the pixel.

FIG. 2 is a partial simplified top view of the image sensor 1 of FIG. 1.

In this top view, the first and second photodetectors have being represented by rectangles and the microlenses have been represented by circles. More particularly, in FIG. 2:
a microlens 18 covers the upper electrode 104A, respectively 104B, of photodetector 10A, respectively 10B, of pixel 10;
a microlens 18 covers the upper electrode 124A, respectively 124B, of photodetector 12A, respectively 12B, of pixel 12;
a microlens 18 covers the upper electrode 144A, respectively 144B, of photodetector 14A, respectively 14B, of pixel 14; and
a microlens 18 covers the upper electrode 164A, respectively 164B, of photodetector 16A, respectively 16B, of pixel 16.

In practice, due to the intervals between electrodes which will appear from the discussion of the following figures, it can be considered that lenses 18 totally cover the respective electrodes of the pixels with which they are associated.

In image sensor 1, in top view in FIG. 2, the pixels are substantially square-shaped, preferably square-shaped. All the pixels of image sensor 1 preferably have identical dimensions, to within manufacturing dispersions.

The square formed by each pixel of image sensor 1, in top view in FIG. 2, has a side length in the range from approximately 0.8 μm to 10 μm, preferably in the range from approximately 0.8 μm to 3 μm, more preferably in the range from 0.8 μm to 3 μm.

The first photodetector and the second photodetector belonging to a same pixel (for example, the first photodetector 10A and the second photodetector 10B of the first pixel 10) both have a rectangular shape. The photodetectors have substantially the same dimensions and are jointly inscribed within the square formed by the pixel to which they belong.

The rectangle formed by each photodetector of each pixel of image sensor 1 has a length substantially equal to the side length of the square formed by each pixel and a width substantially equal to half the side length of the square formed by each pixel. A space is however formed between the first and the second photodetector of each pixel, so that their respective lower electrodes are separate.

In image sensor 1, each microlens 18 has, in top view in FIG. 2, a diameter substantially equal, preferably equal to the side length of the square formed by the pixel to which is belongs. In the present embodiment, each pixel comprises a microlenses 18. Each microlens 18 of image sensor 1 is preferably centered with respect to the square formed by the photodetectors that it covers.

As a variation, each microlens 18 may be replaced with another type of micrometer-range optical element, particularly a micrometer-range Fresnel lens, a micrometer-range index gradient lens, or a micrometer-range diffraction grating. Microlenses 18 are converging lenses, each having a focal distance f in the range from 1 μm to 100 μm, preferably from 1 μm to 10 μm. According to an embodiment, all the microlenses 18 are substantially identical.

Microlenses 18 may be made of silica, of poly(methyl) methacrylate (PMMA), of positive resist, of polyethylene terephthalate (PET), of polyethylene naphthalate (PEN), of cyclo-olefin polymer (COP), of polydimethylsiloxane (PDMS)/silicone, or of epoxy resin. Microlenses 18 may be formed by flowing of resist blocks. Microlenses 18 may further be formed by molding on a layer of PET, PEN, COP, PDMS/silicone or epoxy resin.

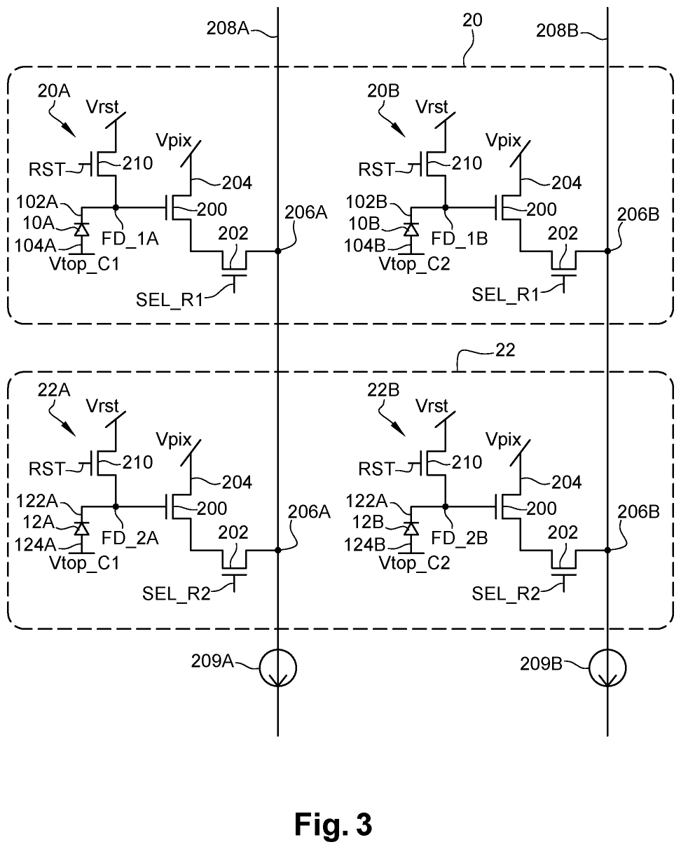

FIG. 3 is an electric diagram of an embodiment of readout circuits of two pixels of the image sensor of FIGS. 1 and 2.

For simplification, only the readout circuits associated with two pixels of image sensor 1 are considered in FIG. 3, for example, pixels 10 and 12 of image sensor 1. In this example, each photodetector is associated with a readout circuit. More particularly, in FIG. 3:
the first photodetector 10A of pixel 10 is associated with a first readout circuit 20A;
the second photodetector 10B of pixel 10 is associated with a second readout circuit 20B;
the first photodetector 12A of pixel 12 is associated with a first readout circuit 22A; and
the second photodetector 12A of pixel 12 is associated with a second readout circuit 22B.

The first readout circuit 20A of the first photodetector 10A of pixel 10 and the second readout circuit 20B of the second photodetector 10B of pixel 10 jointly form a readout circuit 20 of pixel 10. Similarly, the first readout circuit 22A of the first photodetector 12A of pixel 12 and the second readout circuit 22B of the second photodetector 12B of pixel 12 jointly form a readout circuit 22 of pixel 12.

According to this embodiment, each readout circuit 20A, 20B, 22A, 22B comprises three MOS transistors. Such a circuit is currently designated, with its photodetector, by expression “3T sensor”. In particular, in the example of FIG. 3, each readout circuit 20A, 22A associated with a first photodetector comprises a follower-assembled MOS transistor 200, in series with a MOS selection transistor 202, between two terminals 204 and 206A. Similarly, still in the example of FIG. 3, each readout circuit 20B, 22B associated with a second photodetector comprises a follower-assembled MOS transistor 200, in series with a MOS selection transistor 202, between two terminals 204 and 206B.

Each terminal 204 is coupled to a source of a high reference potential, noted Vpix, in the case where the transistors of the readout circuits are N-channel MOS transistors. Each terminal 204 is coupled to a source of a low reference potential, for example, the ground, in the case where the transistors of the readout circuits are P-channel MOS transistors.

Each terminal 206A is coupled to a first conductive track 208A. The first conductive track 208A may be coupled to all the first photodetectors of a same column. The first conductive track 208A is preferably coupled to all the first photodetectors of image sensor 1.

Similarly, each terminal 206B is coupled to a second conductive track 208B. The second conductive track 208B may be coupled to all the second photodetectors of a same column. The second conductive track 208B is preferably coupled to all the second photodetectors of image sensor 1. The second conductive track 208B is preferably separate from the first conductive track 208A.

In the example of FIG. 3, first conductive track 208A is coupled to a first current source 209A which does not form part of the readout circuits 20, 22 of pixels 10, 12 of image sensor 1. Similarly, second conductive track 208B is coupled to a second current source 209B which does not form part of the readout circuits 20, 22 of the pixels 10, 12 of image sensor 1. In other words, the current sources 209A and 209B of image sensor 1 are external to the pixels and readout circuits.

The gate of transistor 202 is intended to receive a signal, noted SEL_R1, of selection of pixel 10 in the case of the readout circuit 20 of pixel 10. The gate of transistor 202 is intended to receive another signal, noted SEL_R2, of selection of pixel 12 in the case of the readout circuit 22 of pixel 12.

In the example of FIG. 3:
the gate of transistor 200 associated with the first photodetector 10A of pixel 10 is coupled to a node FD_1A;
the gate of transistor 200 associated with the second photodetector 10B of pixel 10 is coupled to a node FD_1B;
the gate of the transistor 200 associated with the first photodetector 12A of pixel 12 is coupled to a node FD_2A; and
the gate of the transistor 200 associated with the second photodetector 12B of pixel 12 is coupled to a node FD_2B.

Each node FD_1A, FD_1B, FD_2A, FD_2B is coupled, by a reset MOS transistor 210, to a terminal of application of a reset potential Vrst, which potential may be identical to potential Vpix. The gate of transistor 210 is intended to receive a signal RST for controlling the resetting of the photodetector, particularly enabling to reset node FD_1A, FD_1B, FD_2A, or FD_2B substantially to potential Vrst.

In the example of FIG. 3:
node FD_1A is connected to the cathode electrode 102A of the first photodetector 10A of pixel 10;
node FD_1B is connected to the cathode electrode 102B of the second photodetector 10B of pixel 10;
node FD_2A is connected to the cathode electrode 122A of the first photodetector 12A of pixel 12; and
node FD_2B is connected to the cathode electrode 122B of the second photodetector 12B of pixel 12.

Still in the example of FIG. 3:
the anode electrode 104A of the first photodetector 10A of pixel 10 is coupled to a source of a reference potential Vtop_C1;
the anode electrode 104B of the second photodetector 10B of pixel 10 is coupled to a source of a reference potential Vtop_C2;
the anode electrode 124A of the first photodetector 12A of pixel 12 is coupled to a source of reference potential Vtop_C1; and
the anode electrode 124B of the second photodetector 12B of pixel 12 is coupled to a source of a reference potential Vtop_C2.

In image sensor 1, potential Vtop_C1 is applied to the first upper electrode common to all the first photodetectors. Potential Vtop_C2 is applied to the second upper electrode common to all the second photodetectors.

In the rest of the disclosure, the following notations are arbitrarily used:
VFD_1A for the voltage present at node FD_1A;
VFD_1B for the voltage present at node FD_1B;
VSEL_R1 for the voltage applied to the gate of the transistors 202 of pixel 10, that is, the voltage applied to the gate of the transistor 202 of the first photodetector 10A and the voltage applied to the gate of the transistor 202 of the second photodetector 10B; and
VSEL_R2 for the voltage applied to the gate of the transistors 202 of pixel 12, that is, the voltage applied to the gate of the transistor 202 of the first photodetector 12A and the voltage applied to the gate of the transistor 202 of the second photodetector 12B.

It is considered in the rest of the disclosure that the application of voltage VSEL_R1, respectively VSEL_R2, is controlled by the binary signal noted SEL_R1, respectively SEL_R2.

Other types of sensors, for example, so-called “4T” sensors, are known. The use of organic photodetectors advantageously enables to spare a transistor and to use a 3T sensor.

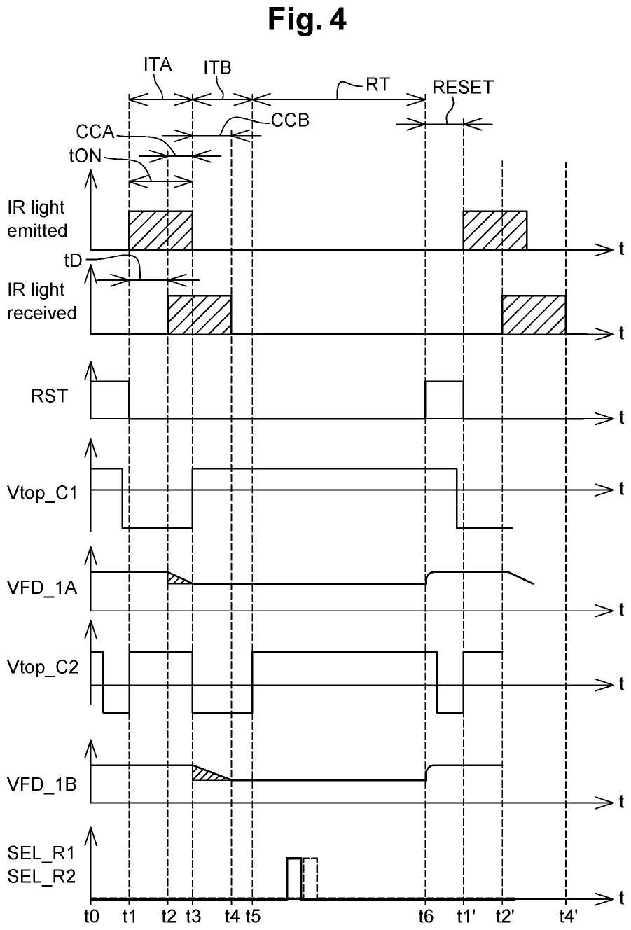

FIG. 4 is a timing diagram of signals of an example of operation of image sensor 1 having the readout circuit of FIG. 3.

The timing diagram of FIG. 4 more particularly corresponds to an example of operation of image sensor 1 in “time of flight” mode. In this operating mode, the pixels of image sensor 1 are used to estimate a distance separating them from a subject (object, scene, face, etc.) placed or located opposite image sensor 1. To estimate this distance, it is started by emitting a light pulse towards the subject with an associated emitter system, not described in the present text. Such a light pulse is generally obtained by briefly illuminating the subject with a radiation originating from a source, for example, a near infrared radiation originating from a light-emitting diode. The light pulse is then at least partially reflected by the subject, and then captured by image sensor 1. A time taken by the light pulse to make a return travel between the source and the subject is then calculated or measured. Image sensor 1 being advantageously located close to the source, this time corresponds to approximately twice the time taken by the light pulse to travel the distance separating the subject from image sensor 1.

The timing diagram 4 illustrates an example of variation of binary signals RST and SEL_R1 as well as potentials Vtop_C1, Vtop_C2, VFD_1A, and VFD_1B of two photodetectors of a same pixel of image sensor 1, for example, the first photodetector 10A and the second photodetector 10B of pixel 10. FIG. 4 also shows, in dotted lines, the binary signal SEL_R2 of another pixel of image sensor 1, for example, pixel 12. The timing diagram of FIG. 4 has been established considering that the MOS transistors of the readout circuit 20 of pixel 10 are N-channel transistors.

At a time t0, signal SEL_R1 is in the low state so that the transistors 202 of pixel 10 are off. A reset phase is then initiated. For this purpose, signal RST is maintained in the high state so that the reset transistors 210 of pixel 10 are on. The charges accumulated in photodiodes 10A and 10B are then discharged towards the source of potential Vrst.

Potential Vtop_C1 is, still at time t0, in a high level. The high level corresponds to a biasing of the first photodetector 10A under a voltage greater than a voltage resulting from the application of a potential called “built-in potential”. The built-in potential is equivalent to a difference between a work function of the anode and a work function of the cathode. When potential Vtop_C1 is in the high level, the first photodetector 10A integrates no charges.

Before a time t1 subsequent to time t0, potential Vtop_C1 is set to a low level. This low level corresponds to a biasing of the first photodetector 10A under a negative voltage, that is, smaller than 0 V. This thus enables first photodetector 10A to integrate photogenerated charges. What has been previously described in relation with the biasing of first photodetector 10A by potential Vtop_C1 transposes to the explanation of the operation of the biasing of the second photodetector 10B by potential Vtop_C2.

At time t1, a first infrared light pulse starts being emitted (IR light emitted) towards a scene comprising one or a plurality of objects, having their distance desired to be measured, which enables to acquire a depth map of the scene. The first infrared light pulse has a duration noted tON. At time t1, signal RST is set to the low state, so that the reset transistors 210 of pixel 10 are off, and potential Vtop_C2 is set to a high level.

Potential Vtop_C1 being at the low level, at time t1, a first integration phase, noted ITA, is started in the first photodetector 10A of pixel 10 of image sensor 1. The integration phase of a pixel designates the phase during which the pixel collects charges under the effect of an incident radiation.

At a time t2, subsequent to time t1 and separated from time t1 by a time period noted tD, a second infrared light pulse originating from the reflection of the first infrared light pulse by an object in the scene or by a point of an object having its distance to pixel 10 desired to be measured, starts being received (IR light received). Time period tD thus is a function of the distance of the object to sensor 1. A first charge collection phase, noted CCA is then started, in first photodetector 10A. The first charge collection phase corresponds to a period during which charges are generated proportionally to the intensity of the incident light, that is, proportionally to the light intensity of the second pulse, in photodetector 10A. The first charge collection phase causes a decrease in the level of potential VFD_1A at node FD_1A of readout circuit 20A.

At a time t3, in the present example subsequent to time t2 and separated from time t1 by time period tON, the first infrared light pulse stops being emitted. Potential Vtop_C1 is simultaneously set to the high level, thus marking the end of the first integration phase, and thus of the first charge collection phase.

At the same time, potential Vtop_C2 is set to a low level. A second integration phase, noted ITB, is then started at time t3 in the second photodetector 10B of pixel 10 of image sensor 1. Given that the second photodetector 10B receives light originating from the second light pulse, a second charge collection phase, noted CCB, is started, still at time t3. The second charge collection phase causes a decrease in the level of potential VFD_1B at node FD_1B of readout circuit 20B.

At a time t4, subsequent to time t3 and separated from time t2 by a time period substantially equal to tON, the second light pulse stops being captured by the second photodetector 10B of pixel 10. The second charge collection phase then ends at time t4.

At a time t5, subsequent to time t4, potential Vtop_C2 is set to the high level. This thus marks the end of the second integration phase.

Between time t5 and a time t6, subsequent to time t5, a readout phase, noted RT, during which the quantity of charges collected by the photodiodes of the pixels of image sensor 1 is measured, is carried out. For this purpose, the pixels rows of image sensor 1 are for example sequentially read. In the example of FIG. 4, signals SEL_R1 and SEL_R2 are successively set to the high state to alternately read pixels 10 and 12 of image sensor 1.

From time t6 and until a time t1′, subsequent to time t6, a new reset phase (RESET) is initiated. Signal RST is set to the high state so that the reset transistors 210 of pixel 10 are turned on. The charges accumulated in photodiodes 10A and 10B are then discharged towards the source of potential Vrst.

Time period tD, which separates the beginning of the first emitted light pulse from the beginning of the second received light pulse, is calculated by means of the following formula:

$$tD = \frac{tON \times Δ VFD\_ 1 B}{ΔVFD\_ 1 A + ΔVFD\_ 1 B} \qquad [ Math 1 ]$$

In the above formula, the quantity noted ΔVFD_1A corresponds to a drop of potential VFD_1A during the integration phase of first photodetector 10A. Similarly, the quantity noted ΔVFD_1B corresponds to a drop of potential VFD_1B during the integration phase of second photodetector 10B.

At time t1′, a new distance estimation is initiated by the emission of a second light pulse. The new distance estimation comprises times t2′ and t4′ similar to times t2 and t4, respectively.

The operation of image sensor 1 has been illustrated hereabove in relation with an example of operation in time-of-flight mode, where the photodetectors of a same pixel are driven in desynchronized fashion. An advantage of image sensor 1 is that it may also operate in other modes, particularly modes where the photodetectors of a same pixel are driven in synchronized fashion. Image sensor 1 may for example be driven in global shutter mode, that is, image sensor 1 may also implement an image acquisition method where beginnings and ends of the pixel integration phases are simultaneous.

An advantage of image sensor 1 thus is to be able to operate alternately according to different modes. Image sensor 1 may for example operate alternately in time-of-flight mode and in global shutter imaging mode.

According to an implementation mode, the readout circuits of the photodetectors of image sensor 1 are alternately driven in other operating modes, for example, modes where image sensor 1 is capable of operating:
in a portion of the infrared spectrum;
in structured light;
in high dynamic range imaging (HDR), by ascertaining that, for each pixel, the integration time of one of the two photodetectors is greater than that of the other photodetector; and/or
with a background suppression.

Image sensor 1 may thus be used to form different types of images with no loss of resolution, since the different imaging modes capable of being implemented by image sensor 1 use a same number of pixels. The use of image sensor 1, capable of integrating a plurality of functionalities in a same pixel array and readout circuits, particularly enables to respond to the current constraints of miniaturization of electronic devices, for example, smart phone design and manufacturing constraints.

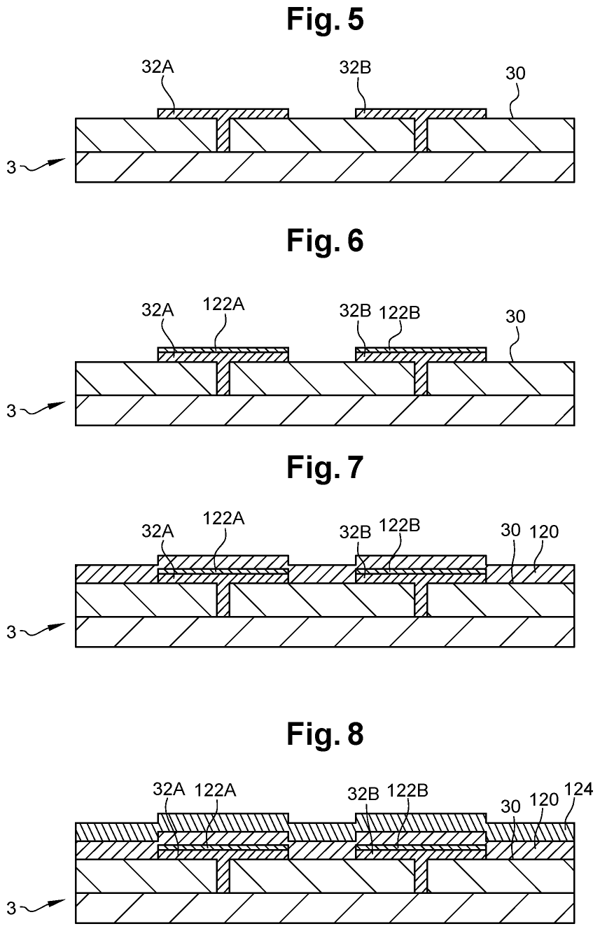

FIGS. 5 to 13 hereafter illustrate successive steps of an implementation mode of a method of forming the image sensor 1 of FIGS. 1 and 2. For simplification, what is discussed hereafter in relation with FIGS. 5 to 13 illustrates the forming of a single pixel of image sensor 1, for example, the pixel 12 of image sensor 1. However, it should be understood that this method may be extended to the forming of any number of pixels of an image sensor similar to image sensor 1.

FIG. 5 is a partial simplified cross-section view of a step of an implementation mode of a method of forming the image sensor 1 of FIGS. 1 and 2.

According to this implementation mode, it is started by providing CMOS support 3, particularly comprising the readout circuits (not shown) of pixel 12. CMOS support 3 further comprises, at its upper surface 30, contacting elements 32A and 32B. Contacting elements 32A and 32B have, in cross-section view in FIG. 5, a “T”-shape, where:
a horizontal portion extends on upper surface 30 of CMOS support 3; and
a vertical portion extends downwards from the upper surface 30 of CMOS support 3 to contact lower metallization levels (not shown) of CMOS support 3 coupled or connected to the readout circuits (not shown).

Contacting elements 32A and 32B are for example formed from conductive tracks formed on the upper surface 30 of CMOS support 3 (horizontal portions of contacting elements 32A and 32B) and from conductive vias (vertical portions of contacting elements 32A and 32B) contacting the conductive tracks. The conductive tracks and the conductive vias may be made of a metallic material, for example, silver (Ag), aluminum (Al), gold (Au), copper (Cu), nickel (Ni), titanium (Ti), and chromium (Cr), or of titanium nitride (TiN). The conductive tracks and the conductive vias may have a monolayer or multilayer structure. In the case where the conductive tracks have a multilayer structure, the conductive tracks may be formed by a stack of conductive layers separated by insulating layers. The vias then cross the insulating layers. The conductive layers may be made of a metallic material from the above list and the insulating layers may be made of silicon nitride (SiN) or of silicon oxide (SiO₂).

During this same step, CMOS support 3 is cleaned to remove possible impurities present at its surface 30. The cleaning is for example performed by plasma. The cleaning thus provides a satisfactory cleanness of CMOS support 3 before a series of successive depositions, detailed in relation with the following drawings, is performed.

In the rest of the disclosure, the implementation mode of the method described in relation with FIGS. 6 to 13 exclusively comprises performing operations above the upper surface 30 of CMOS support 3. The CMOS support 3 of FIGS. 6 to 13 thus preferably is identical to the CMOS support 3 such as discussed in relation with FIG. 5 all along the method. For simplification, CMOS support 3 will not be detailed again in the following drawings.

FIG. 6 is a partial simplified cross-section view of another step of the implementation mode of the method of forming the image sensor 1 of FIGS. 1 and 2 from the structure such as described in relation with FIG. 5.

During this step, an electron injection material is deposited at the surface of contacting elements 32A and 32B. A material selectively bonding to the surface of contacting elements 32A and 32B is preferably deposited to form a self-assembled monolayer (SAM). This deposition thus preferably or only covers the free upper surfaces of contacting elements 32A and 32B. One thus forms, as illustrated in FIG. 6:
the lower electrode 122A of the first organic photodetector 12A of pixel 12; and
the lower electrode 122B of the second organic photodetector 12B of pixel 12.

As a variant, a full plate deposition of an electron injection material having a sufficiently low lateral conductivity to avoid creating conduction paths between two neighboring contacting elements is performed.

Lower electrodes 122A and 122B form electron injection layers (EIL) and photodetectors 12A and 12B, respectively. Lower electrodes 122A and 122B are also called cathodes of photodetectors 12A and 12B. Lower electrodes 122A and 122B are preferably formed by spin coating or by dip coating.

The material forming lower electrodes 122A and 122B is selected from the group comprising:
a metal or a metallic alloy, for example, silver (Ag), aluminum (Al), lead (Pb), palladium (Pd), gold (Au), copper (Cu), nickel (Ni), tungsten (W), molybdenum (Mo), titanium (Ti), chromium (Cr), or an alloy of magnesium and silver (MgAg);
a transparent conductive oxide (TCO), particularly indium tin oxide (ITO), aluminum zinc oxide (AZO), gallium zinc oxide (GZO), an ITO/Ag/ITO multilayer, an ITO/Mo/ITO multilayer, a AZO/Ag/AZO multilayer, or a ZnO/Ag/ZnO multilayer;
a polyethyleneimine (PEI) polymer or a polyethyleneimine ethoxylated (PEIE), propoxylated, and/or butoxylated polymer;
carbon, silver, and/or copper nanowires;
graphene; and
a mixture of at least two of these materials.

Lower electrodes 122A and 122B may have a monolayer or multilayer structure.

FIG. 7 is a partial simplified cross-section view of still another step of the embodiment of the method of forming the image sensor 1 of FIGS. 1 and 2 from the structure such as described in relation with FIG. 6.

During this step, a non-selective deposition of a first layer 120 is performed on the upper surface side 30 of CMOS support 3. The deposition is called “full plate” deposition since it covers the entire upper surface 30 of CMOS support 3 as well as the free surfaces of contacting elements 32A, 32B and of lower electrodes 122A and 122B. The deposition of first layer 120 is preferably performed by spin coating.

According to this implementation mode, the first layer 120 is intended to form the future active layers 120A, 120B of the photodetectors 12A and 12B of pixel 12. The active layers 120A and 120B of the photodetectors 12A and 12B of pixel 12 preferably have a composition and a thickness identical to those of first layer 120.

First layer 120 may comprise small molecules, oligomers, or polymers. These may be organic or inorganic materials, particularly comprising quantum dots. First layer 120 may comprise an ambipolar semiconductor material, or a mixture of an N-type semiconductor material and of a P-type semiconductor material, for example in the form of stacked layers or of an intimate mixture at a nanometer scale to form a bulk heterojunction. The thickness of first layer 120 may be in the range from 50 nm to 2 μm, for example, in the order of 300 μm.

Examples of P-type semiconductor polymers capable of forming layer 120 are:
poly(3-hexylthiophene) (P3HT);
poly[N-9′-heptadecanyl-2,7-carbazole-alt-5,5-(4,7-di-2-thienyl-2′,1′,3′-benzothiadiazole] (PCDTBT);
poly[(4,8-bis-(2-ethylhexyloxy)-benzo[1,2-b;4,5-b′]dithiophene)-2,6-diyl-alt-(4-(2-ethylhexanoyl)-thieno[3,4-b]thiophene))-2,6-diyl] (PBDTTT-C);
poly[2-methoxy-5-(2-ethyl-hexyloxy)-1,4-pheny-lene-vinylene] (MEH-PPV); and
poly[2,6-(4,4-bis-(2-ethylhexyl)-4H-cyclopenta [2,1-b;3,4-b′]dithiophene)-alt-4,7(2,1,3-benzothiadiazole)] (PCPDTBT).

Examples of N-type semiconductor materials capable of forming layer 120 are fullerenes, particularly C60, [6,6]-phenyl-C₆₁-methyl butanoate ([60]PCBM), [6,6]-phenyl-C₇₁-methyl butanoate ([70]PCBM), perylene diimide, zinc oxide (ZnO), or nanocrystals enabling to form quantum dots.

FIG. 8 is a partial simplified cross-section view of still another step of the embodiment of the method of forming the image sensor 1 of FIGS. 1 and 2 from the structure such as described in relation with FIG. 7.

During this step, a non-selective deposition of a second layer 124 is performed on the upper surface side of CMOS support 3. The deposition is called “full plate” deposition since it covers the entire upper surface of first layer 120. The deposition of second layer 124 is preferably performed by spin coating.

According to this implementation mode, the second layer 124 is intended to form the future upper electrodes 124A, 124B of the photodetectors 12A and 12B of pixel 12. The upper electrodes 124A and 124B of the photodetectors 12A and 12B of pixel 12 preferably have a composition and a thickness identical to those of second layer 124.

Second layer 124 is at least partially transparent to the light radiation that it receives. Second layer 124 may be made of a transparent conductive material, for example, of transparent conductive oxide (TCO), of carbon nanotubes, of graphene, of a conductive polymer, of a metal, or of a mixture or an alloy of at least two of these compounds. Second layer 124 may have a monolayer or multilayer structure.

Examples of TCOs capable of forming second layer 124 are indium tin oxide (ITO), aluminum zinc oxide (AZO), gallium zinc oxide (GZO), titanium nitride (TiN), molybdenum oxide (MoO₃), and tungsten oxide (WO₃). An example of a conductive polymer capable of forming second layer 124 is the polymer known as PEDOT:PSS, which is a mixture of poly(3,4)-ethylenedioxythiophene and of sodium poly(styrene sulfonate), and polyaniline, also called PAni. Examples of metals capable of forming second layer 124 are silver, aluminum, gold, copper, nickel, titanium, and chromium. An example of a multilayer structure capable of forming second layer 124 is a multilayer AZO and silver structure of AZO/Ag/AZO type.

The thickness of second layer 124 may be in the range from 10 nm to 5 μm, for example, in the order of 30 μm. In the case where second layer 124 is metallic, the thickness of second layer 124 is smaller than or equal to 20 nm, preferably smaller than or equal to 10 nm.

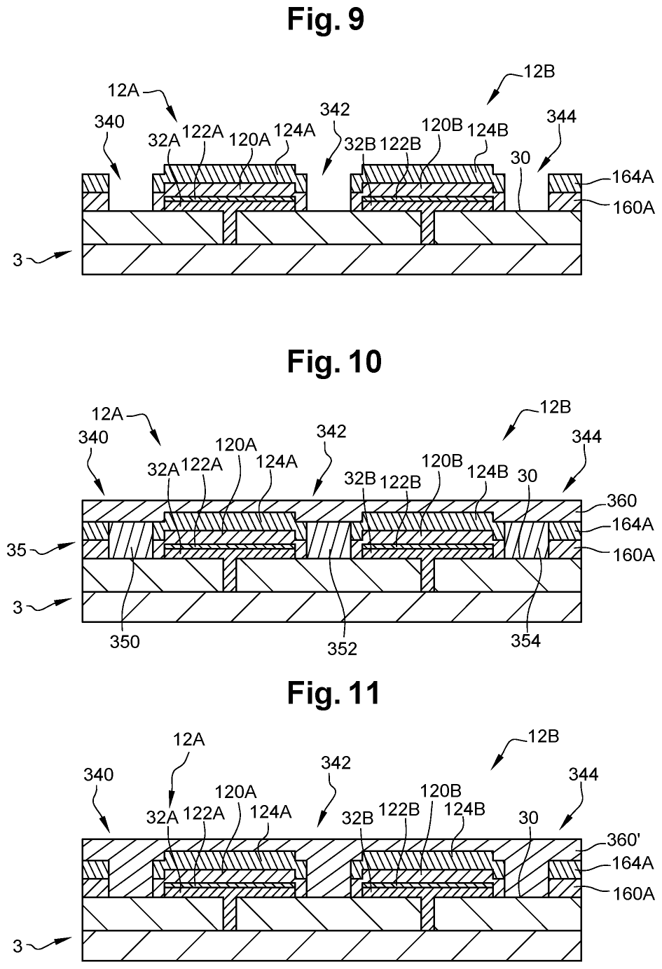

FIG. 9 is a partial simplified cross-section view of still another step of the implementation mode of the method of forming the image sensor of FIGS. 1 and 2 from the structure such as described in relation with FIG. 8.

During this step, three vertical openings 340, 342, and 244 are formed through first layer 120 and second layer 124 down to the upper surface 30 of CMOS support 3. These openings are preferably formed by etching after masking of the areas to be protected, for example, by resist deposition, exposure through a mask, and then dry etching, for example, by reactive ion etching, or by wet etching, for example, by chemical etching. As a variant, the deposition of the etch mask is performed locally, for example, by silk-screening, by heliography, by nano imprint, or by flexography, and the etching is performed by dry etching, for example by reactive ion etching, or by wet etching, for example by chemical etching.

In the example of FIG. 9:
vertical openings 340 and 342 are located on either side of the first contacting element 32A (respectively to the left and to the right of first contacting element 32A); and
vertical openings 342 and 344 are located on either side of the second contacting element 32B (respectively to the left and to the right of second contacting element 32B).

Vertical openings 340, 342, and 344 aim at separating photodetectors belonging to a same row of image sensor 1. Openings 340, 342, and 344 are for example formed by photolithography. As a variant, openings 340, 342, and 344 are formed by reactive ion etching or by chemical etching by means of an adequate solvent.

One thus obtains, as illustrated in FIG. 9:
the active layer 120A of the first photodetector 12A of pixel 12, which totally covers the free surfaces of the first contacting element 32A and lower electrode 122A;
the active layer 120B of the second photodetector 12B of pixel 12, which totally covers the free surfaces of the second contacting element 32B and lower electrode 122B;
the upper electrode 124A of the first photodetector 12A of pixel 12, covering active layer 120A; and
the upper electrode 124B of the second photodetector 12B of pixel 12, covering active layer 120B.

Thus, still in the example of FIG. 9:
opening 340 is interposed between, on the one hand, the active layer 120A and the upper electrode 124A of the first photodetector 12A of pixel 12 and, on the other hand, an active layer and an upper electrode of a second photodetector belonging to a neighboring pixel (not shown);
opening 342 is interposed between, on the one hand, the active layer 120A and the upper electrode 124A of the first photodetector 12A of pixel 12 and, on the other hand, the active layer 120B and the upper electrode 124B of the second photodetector 12B of pixel 12; and
opening 344 is interposed between, on the one hand, the active layer 120B and the upper electrode 124B of the second photodetector 12B of pixel 12 and, on the other hand, the active layer 160A and the upper electrode 164A of the first photodetector of pixel 16 (partially shown in FIG. 9).

Upper electrodes 124A and 124B form hole injection layers (HIL) of photodetectors 12A and 12B, respectively. Upper electrodes 124A and 124B are also called anodes of photodetectors 12A and 12B.

Upper electrodes 124A and 12B are preferably made of the same material as the layer 124 where they are formed, as discussed in relation with FIG. 8.

FIG. 10 is a partial simplified cross-section view of still another step of the embodiment of the method of forming the image sensor 1 of FIGS. 1 and 2 from the structure such as described in relation with FIG. 9.

During this step, openings 340, 342, and 344 are filled with a third insulating layer 35, only portions 350, 352, and 354 of which are shown in FIG. 10. Portions 350, 352, and 354 of this insulation layer 35 respectively fill openings 340, 342, and 344.

Portions 350, 352, and 354 of third layer 35 aim at electrically insulating neighboring photodetectors belonging to a same row of image sensor 1. According to an embodiment, portions 350, 352, and 354 of third layer 35 at least partially absorb the light received by image sensor 1 to optical isolate the photodetectors of the same row. The third insulation layer may be formed from a resin having its absorption at least covering the wavelengths of the photodiodes (visible and infrared). Such a resin, having a black-colored aspect, is then called “black resin”. In the example of FIG. 10, portion 352 electrically and optically insulates the first photodetector 12A from the second photodetector 12B of pixel 12.

The third insulating layer 35 may be made of an inorganic material, for example, of silicon oxide (SiO₂) or of silicon nitride (SiN). In the case where the third insulating layer 35 is made of silicon nitride, this material is preferably obtained by physical vapor deposition (PVD) or by plasma-enhanced chemical vapor deposition (PECVD).

Third insulating layer 35 may be made of a fluorinated polymer, particularly the fluorinated polymer commercialized under trade name “Cytop” by Bellex, of polyvinylpyrrolidone (PVP), of polymethyl methacrylate (PMMA), of polystyrene (PS), of parylene, of polyimide (PI), of acrylonitrile butadiene styrene (ABS), of polydimethylsiloxane (PDMS), of a photolithography resin, of epoxy resin, of acrylate resin, or of a mixture of at least two of these compounds.

As a variant, this insulating layer 35 may be made of another inorganic dielectric, particular of aluminum oxide (Al₂O₃). The aluminum oxide may be deposited by atomic layer deposition (ALD). The maximum thickness of third insulating layer 35 may be in the range from 50 nm to 2 μm, for example, in the order of 100 nm.

A fourth layer 360 is then deposited over the entire structure on the side of upper surface 30 of CMOS support 3. Fourth layer 360 is preferably a so-called “planarization” layer enabling to obtain a structure having a planar upper surface before the encapsulation of the photodetectors.

Fourth planarization layer 360 may be made of a polymer-based dielectric material. Planarization layer 360 may as a variant contain a mixture of silicon nitride (SiN) and of silicon oxide (SiO₂), this mixture being obtained by sputtering, by physical vapor deposition (PVD) or by plasma-enhanced chemical vapor deposition (PECVD).

Planarization layer 360 may also be made of a fluorinated polymer, particularly the fluorinated polymer commercialized under trade name “Cytop” by Bellex, of polyvinylpyrrolidone (PVP), of polymethyl methacrylate (PMMA), of polystyrene (PS), of parylene, of polyimide (PI), of acrylonitrile butadiene styrene (ABS), of polydimethylsiloxane (PDMS), of a photolithography resin, of epoxy resin, of acrylate resin, or of a mixture of at least two of these compounds.

FIG. 11 is a partial simplified cross-section view of a variant of the implementation mode of the method of forming the image sensor 1 of FIGS. 1 and 2 from the structure such as described in relation with FIG. 9.

This variant differs from the step discussed in relation with FIG. 10 mainly in that openings 340, 342, and 344 are here not respectively filled with portions 350, 352, and 354 of third insulating layer 35 but with a layer 360′ preferably made of a material identical to that of fourth layer 360. In other words, the variant illustrated in FIG. 11 amounts not to depositing third insulating layer 35 and to directly depositing fourth layer 360 to form fifth layer 360′. In this case, only the transparent materials listed for fourth layer 360 as discussed in relation with FIG. 10 are capable of forming fifth layer 360′. In particular, fifth layer 360′ is not formed of black resin.

It is assumed in the rest of the disclosure that the variant discussed in relation with FIG. 11 is not retained in the implementation mode of the method. However, the adaptation of the following steps to a case where fifth layer 360′ is formed instead of portions 350, 352, and 354 of third layer 35 and of fourth layer 360 is within the abilities of those skilled in the art based on the indications provided hereafter.

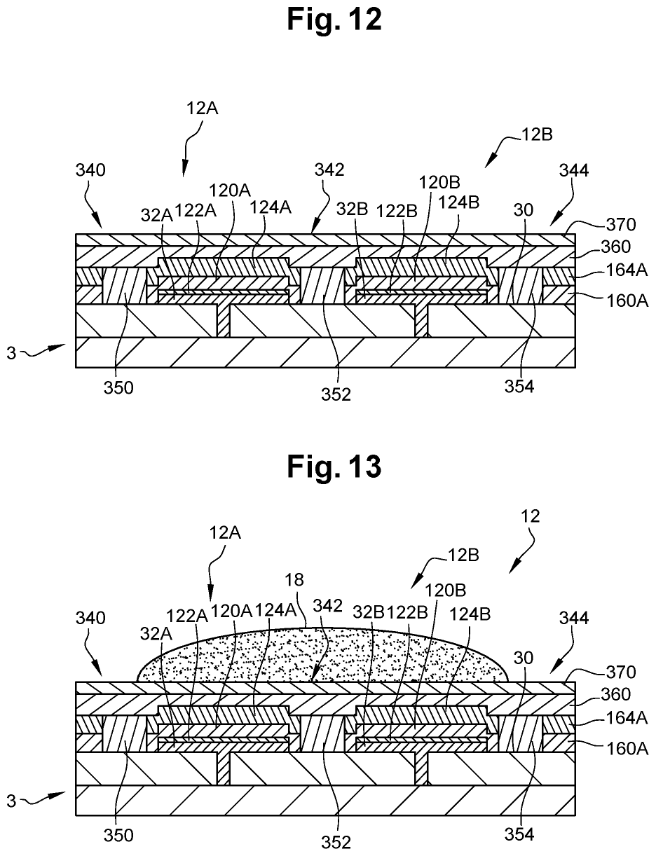

FIG. 12 is a partial simplified cross-section view of still another step of the embodiment of the method of forming the image sensor 1 of FIGS. 1 and 2 from the structure such as described in relation with FIG. 10.

During this step, a sixth layer 370 is deposited all over the structure on the side of upper surface 30 of CMOS support 3. Sixth layer 370 aims at encapsulating the organic photodetectors of image sensor 1. Sixth layer 370 thus enables to avoid the degradation, due to an exposure to water or to the humidity contained in the ambient air, of the organic materials forming the photodetectors of image sensor 1. In the example of FIG. 12, sixth layer 370 covers the entire free upper surface of fourth planarization layer 360.

Sixth layer 370 may be made of alumina (Al₂O₃) obtained by an atomic layer deposition method (ALD), of silicon nitride (Si₃N₄) or of silicon nitride (SiO₂) obtained by physical vapor deposition (PVD), of silicon nitride obtained by plasma-enhanced chemical vapor deposition (PECVD). Sixth layer 370 may as a variant be made of PET, of PEN, of COP, or of CPI.

According to an implementation mode, sixth layer 370 enables to further improve the surface condition of the structure before the forming of microlenses.

FIG. 13 is a partial simplified cross-section view of still another step of the embodiment of the method of forming the image sensor 1 of FIGS. 1 and 2 from the structure such as described in relation with FIG. 12.

During this step, microlens 18 of pixel 12 is formed vertically in line with photodetectors 12A and 12B. In the example of FIG. 13, microlens 18 is substantially centered with respect to the opening 342 separating the two photodetectors 12A, 12B. In other words, microlens 18 is approximately aligned with respect to portion 352 of third insulating layer 35 (FIG. 10). The pixel 12 of image sensor 1 is thus obtained.

According to the considered materials, the method of forming the layers of image sensor 1 may correspond to a so-called additive process, for example, by direct printing of the material forming the organic layers at the desired locations, particularly in sol-gel form, for example, by inkjet printing, photogravure, silk-screening, flexography, spray coating, or drop casting. According to the considered materials, the method of forming the layers of the image sensor may correspond to a so-called subtractive method, where the material forming the organic layer is deposited all over the structure and where the non-used portions are then removed, for example, by photolithography or laser ablation. According to the considered material, the deposition over the entire structure may be performed, for example, by liquid deposition, by cathode sputtering, or by evaporation. Methods such as spin coating, spray coating, heliography, slot-die coating, blade coating, flexography, or silk-screening, may in particular be used. When the layers are metallic, the metal is for example deposited by evaporation or by cathode sputtering over the entire support and the metal layers are delimited by etching.

Advantageously, at least some of the layers of the image sensor may be formed by printing techniques. The materials of the previously-described layers may be deposited in liquid form, for example, in the form of conductive and semiconductor inks by means of inkjet printers. “Materials in liquid form” here also designates gel materials capable of being deposited by printing techniques. Anneal steps may be provided between the depositions of the different layers, but it is possible for the anneal temperatures not to exceed 150° C., and the deposition and the possible anneals may be carried out at the atmospheric pressure.

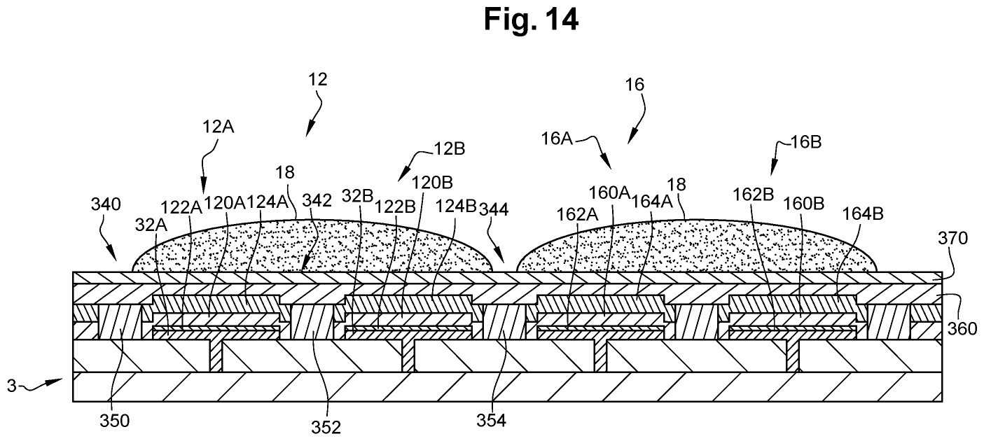

FIG. 14 is a partial simplified cross-section view along plane AA (FIG. 2) of the image sensor 1 of FIGS. 1 and 2. Cross-section plane AA corresponds to a cross-section plane parallel to a pixel row of image sensor 1.

In FIG. 14, only the pixels 12 and 16 of image sensor 1 have been shown. Pixels 12 and 16 belong to a same row of pixels of image sensor 1. In the example of FIG. 14, the photodetectors 12A, 12B of pixel 12 and the photodetectors 16A, 16B of pixel 16 are separated from one another. Thus, along a same row of image sensor 1, each photodetector is insulated from the neighboring photodetectors.

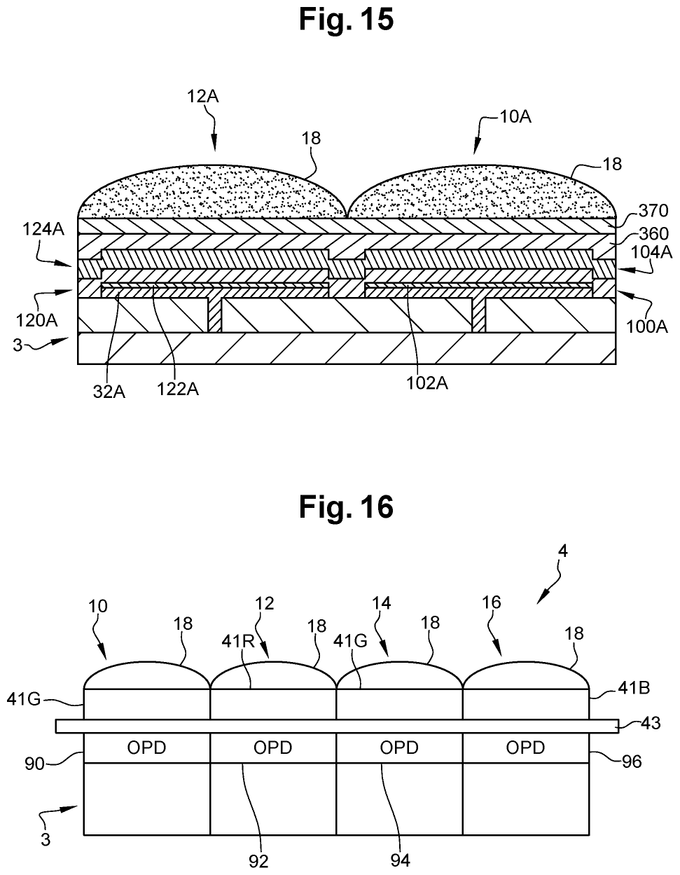

FIG. 15 is a partial simplified cross-section view along plane BB (FIG. 2) of the image sensor 1 of FIGS. 1 and 2. Cross-section plane BB corresponds to a cross-section plane parallel to a pixel column of image sensor 1.

In FIG. 15, only the first photodetectors 10A and 12A of pixels 10 and 12, respectively, are visible. In the example of FIG. 15:
the lower electrode 102A of the first photodetector 10A of pixel 10 is separated from the lower electrode 122A of the first photodetector 12A of pixel 12;
the active layer 100A of the first photodetector 10A of pixel 10 and the active layer 120A of the first photodetector 12A of pixel 12 are formed by a same continuous deposition; and
the upper electrode 104A of the first photodetector 10A of pixel 10 and the upper electrode 124A of the first photodetector 12A of pixel 12 are formed by a same other continuous deposition.

In other words, all the first photodetectors of the pixels belonging to a same pixel column of image sensor 1 have a common active layer and a common upper electrode. The upper electrode thus enables to address all the first photodetectors of the pixels of a same column while the lower electrode enables to individually address each first photodetector.

Similarly, all the second photodetectors of the pixels belonging to a same pixel column of image sensor 1 have a common active layer and a common upper electrode of the first photodetectors of these same pixels, and another common upper electrode, separate from the common upper electrode of the first photodetectors of these same pixels. This other common upper electrode thus enables to address all the second photodetectors of the pixels of a same column while the lower electrode enables to individually address each second photodetector.

FIG. 16 is a partial simplified cross-section view of another embodiment of an image sensor 4.

The image sensor 4 shown in FIG. 16 is similar to the image sensor 1 discussed in relation with FIGS. 1 and 2. Image sensor 4 differs from image sensor 1 mainly in that:
the pixels 10, 12, 14, and 16 of image sensor 4 belong to a same row or to a same column of image sensor 4 (while the pixels 10, 12, 14, and 16 of image sensor 1 (FIG. 1) are distributed on two different rows and two different columns of image sensor 1); and
each pixel 10, 12, 14, and 16 of image sensor 4 has a color filter 41R, 41G, or 41B under its microlens 18 and on a passivation layer 43. In other words, the four monochromatic pixels 10, 12, 14, and 16 arranged in a square in FIG. 1 are here placed side by side in FIG. 16.

More particularly, in the example of FIG. 16, image sensor 4 comprises:
a first green filter 41G, interposed between the microlens 18 of pixel 10 and passivation layer 43;
a red filter 41R, interposed between the microlens 18 of pixel 12 and passivation layer 43;
a second green filter 41G, interposed between the microlens 18 of pixel 14 and passivation layer 43; and
a blue filter 41B, interposed between the microlens 18 of pixel 16 and passivation layer 43.

According to this embodiment, the color filters 41R, 41G, and 41B of image sensor 4 give way to electromagnetic waves in frequency ranges different from the visible spectrum and give way to the electromagnetic waves of the infrared spectrum. Color filters 41R, 41G, and 41B may correspond to colored resin blocks. Each color filter 41R, 41G, and 41B is capable of giving way to the infrared radiation, for example, at a wavelength between 700 nm and 1 mm and, for at least some of the color filters, of giving way to a wavelength range of visible light.

For each pixel of a color image to be acquired, image sensor 4 may comprise:
at least one pixel (for example, pixel 16) having its color filter 41B capable of giving way to infrared radiation and blue light, for example, in the wavelength range from 430 nm to 490 nm;
at least one pixel (for example, pixels 10 and 14) having its color filter 41G capable of giving way to infrared radiation and blue light, for example, in the wavelength range from 510 nm to 570 nm; and
at least one pixel (for example, pixel 12) having its color filter 41R capable of giving way to infrared radiation and red light, for example, in the wavelength range from 600 nm to 720 nm.

Similarly to the image sensor 1 discussed in relation with FIGS. 1 and 2, each pixel 10, 12, 14, 16 of image sensor 4 has a first and a second photodetector. Each pixel thus comprises two photodetectors, very schematically shown in FIG. 16 by a same block (OPD). More particularly, in FIG. 16:
pixel 10 comprises two organic photodetectors (block 90, OPD);
pixel 12 comprises two organic photodetectors (block 92, OPD);
pixel 14 comprises two organic photodetectors (block 94, OPD); and
pixel 16 comprises two organic photodetectors (block 96, OPD).

The photodetectors of each pixel 10, 12, 14, and 16 are coplanar and each associated with a readout circuit, as discussed in relation with FIG. 3. The readout circuits are formed on top of an inside of CMOS support 3. Image sensor 4 is thus capable, for example, of alternately performing time-of-flight distance estimates in infrared and color image captures.

Various embodiments, implementation modes, and variations have been described. Those skilled in the art will understand that certain features of these various embodiments, implementation modes, and variants may be combined, and other variants will occur to those skilled in the art.

Finally, the practical implementation of the described embodiments, implementation modes, and variations is within the abilities of those skilled in the art based on the functional indications given hereabove. In particular, the adaptation of the driving of the readout circuits of image sensors 1 to 4 to other operating modes, for example, for the forming of infrared images with or without added light, the forming of images with a background suppression, and the forming of high-dynamic range images (simultaneous HDR) is within the abilities of those skilled in the art based on the above indications.

1. A pixel comprising:
a CMOS support; and
first and second organic photodetectors,
wherein a same lens is vertically in line with said organic photodetectors.

2. An image sensor comprising a plurality of pixels, each of the pixels comprising:
a CMOS support; and
first and second organic photodetectors,
wherein a same lens is vertically in line with said organic photodetectors.

3. A method of manufacturing the pixel according to claim 1, comprising steps of:
providing a CMOS support;
forming at least two organic photodetectors; and
forming a same lens vertically in line with the organic photodetectors of the pixel.

4. The pixel according to claim 1, wherein said organic photodetectors are coplanar.

5. The pixel according to claim 1, wherein said organic photodetectors are separated from one another by a dielectric.

6. The pixel according to claim 1, wherein each organic photodetector comprises a first electrode, separate from first electrodes of the other organic photodetectors, formed at the surface of the CMOS support.

7. The pixel according to claim 6, wherein each first electrode is coupled to a readout circuit, each readout circuit comprising three transistors formed in the CMOS support.

8. The pixel according to claim 1, wherein said organic photodetectors estimate a distance by time of flight.

9. The pixel according to claim 1, wherein the pixel operates:
in a portion of the infrared spectrum;
in structured light;
in high dynamic range imaging, HDR; and/or
with a background suppression.

10. The image sensor according to claim 2, wherein each pixel further comprises, under the lens, a color filter giving way to electromagnetic waves in a frequency range of the visible spectrum and in the infrared spectrum.

11. The image sensor according to claim 10, wherein the image sensor captures a color image.

12. The pixel according to claim 1, wherein the pixel comprises only two organic photodetectors including:
the first organic photodetector; and
the second organic photodetector.

13. The pixel according to claim 12, wherein the first organic photodetector and the second organic photodetector have a rectangular shape and are jointly inscribed within a square.

14. The pixel according to claim 12, wherein each organic photodetector comprises a first electrode, separate from first electrode of the other organic photodetector, formed at the surface of the CMOS support and wherein:
the first organic photodetector is connected to a second electrode; and
the second organic photodetector is connected to a third electrode.

15. The image sensor of claim 17, wherein:
the second electrode is common to all the first organic photodetectors of the pixels of the sensor; and
the third electrode is common to all the second organic photodetectors of the pixels of the sensor.

16. The image sensor according to claim 2, wherein each pixel comprises only two organic photodetectors including:
the first organic photodetector;
the second organic photodector.

17. The image sensor according to claim 16, wherein each organic photodetector comprises a first electrode, separate from first electrode of the other organic photodetector, formed at the surface of the CMOS support, and for each pixel:
the first organic photodetector is connected to a second electrode; and
the second organic photodetector is connected to a third electrode.

18. The image sensor according to claim 2, wherein said organic photodetectors are coplanar.

19. The image sensor according to claim 2, wherein said organic photodetectors are separated from one another by a dielectric.

20. A method of manufacturing the image sensor according to claim 2, comprising steps of:
providing a CMOS support;
forming at least two organic photodetectors per pixel; and
forming a same lens vertically in line with the organic photodetectors of each pixel.
